(19) United States
(12) Patent Application Publication
(10) Pub. No.: US 2001/0001732 A1
(43) Pub. Date: May 24, 2001

(54) PROCESS FOR FABRICATING SEMICONDUCTOR DEVICE WITHOUT ETCHING RESIDUE PRODUCED DURING ETCHING TO OXIDE LAYER

(76) Inventor: AKIRA MITSUIKI, TOKYO (JP)

Correspondence Address: HELFGOTT & KARAS PC, EMPIRE STATE BUILDING, 60TH FLOOR, NEW YORK, NY, 10118

(21) Appl. No.: 09/306,625

(22) Filed: May 6, 1999

(30) Foreign Application Priority Data
May 8, 1998 (JP) 10-126375

(51) Int. Cl. H01L 21/302; H01L 21/461

(52) U.S. Cl. 438/689

(57) ABSTRACT

A photo-resist etching mask is formed on a silicon oxide layer deposited on a polysilicon layer, and the silicon oxide and the polysilicon are respectively etched by using gaseous etchant containing CF₄ and another gaseous etchant containing HBr and O₂, wherein etching residue of fluorocarbon and a surface portion of the polysilicon layer are etched away by using Cl₂ gas so as to pattern the polysilicon without undesirable influence of the etching residue.

### FIELD OF THE INVENTION

This invention relates to a fabrication technology for a semiconductor device and, more particularly, to a process for fabricating a semiconductor device having a semiconductor layer and an oxide layer laminated on the semiconductor layer.

### DESCRIPTION OF THE RELATED ART

In a fabrication of a semiconductor device, a semiconductor layer such as a polysilicon layer is sometimes patterned by using a silicon oxide layer as an etching mask. A silicon oxide layer on a polysilicon layer is, by way of example, patterned into an etching mask, and, thereafter, the polysilicon layer is patterned into a gate electrode of a field effect transistor. A flush memory has a silicon oxide layer and a silicon nitride layer between a floating gate electrode and a control gate electrode, and the floating gate electrode and the control gate electrode are usually formed of polysilicon. The silicon oxide layer is laminated on the polysilicon layer. It is necessary to pattern the silicon oxide layer and the polysilicon layer into the inter-gate insulating layer and the floating gate electrode.

If the silicon oxide layer and the polysilicon layer are patterned in different etching systems, the patterning process becomes complicated, and the manufacturer suffers from low-throughput. In order to make the successive patterning step simple, only gaseous etchant is changed between the silicon oxide layer and the polysilicon layer. While the laminated structure is successively patterned, a kind of gaseous etchant with large selectivity to the silicon oxide is firstly supplied to the reactor of an etching system for patterning the silicon oxide layer, and the gaseous etchant is changed to another kind of gaseous etchant with large selectivity to the polysilicon. A typical example of the gaseous etchant for the silicon oxide is in CF system, and the gaseous etchant for the polysilicon is gaseous mixture of Cl₂/HBr/O₂. The operator is only expected to change the gaseous etchant without relocation of a silicon wafer. However, the manufacturer encounters a problem in the prior art successive patterning step in that etching residue and residual photo-resist serve as an unintentional etching mask.

In detail, FIGS. 1A to 1C illustrate the prior art process. The manufacturer prepares a silicon wafer 1, and a silicon oxide layer 2 is grown on the major surface of the silicon wafer 1. Polysilicon is deposited over the entire surface, and forms a polysilicon layer 3. Silicon oxide is deposited over the polysilicon layer 3, and forms a silicon oxide layer 4. Photo-resist solution is spread over the entire surface of the silicon oxide layer 4, and is baked so that a photo-resist layer is formed from the photo-resist layer. A pattern image is transferred to the photo-resist layer, and a latent image is produced in the photo-resist layer. The latent image is developed, and a photo-resist etching mask 5 is left on the silicon oxide layer 4. A part of the silicon oxide layer 4 is exposed to an opening 5a formed in the photo-resist etching mask 5 as shown in FIG. 1A.

Subsequently, the silicon oxide layer 4 is selectively etched by using a kind of gaseous etchant in the CF system. The gaseous etchant in the CF system may contain CF₄, CHF₃ or C₄F₈. While the silicon oxide layer 4 is being etched in the gaseous etchant, pieces 6 of etching residue are produced, and are left on the polysilicon layer 3 as shown in FIG. 1B. The etching residue is fluorocarbon and the photo-resist.

Upon completion of the patterning to the silicon oxide layer 4, the gaseous etchant is changed to gaseous mixture containing Cl₂, HBr and O₂, and the polysilicon layer 3 is selectively etched. The pieces 6 of etching residue on the polysilicon layer 3 prevent the polysilicon layer 3 from the attack of the gaseous etchant, and serve as an unintentional etching mask. As a result, pieces 7 of residual polysilicon are left on the silicon oxide layer 2.

### SUMMARY OF THE INVENTION

It is therefore an important object of the present invention to provide a process for successively patterning an oxide layer and a semiconductor layer without residual semiconductor pieces.

To accomplish the object, the present invention proposes to use an etchant having large selectivity to both of the etching residue and the semiconductor.

In accordance with one aspect of the present invention, there is provided a process for fabricating a semiconductor device, comprising the steps of (a) preparing a semiconductor structure having a first layer formed of a predetermined material, a second layer formed of a semiconductor material and laminated on the first layer and a third layer formed of an oxide and laminated on the second layer, (b) etching the third layer by using a first etchant having a first selectivity to the oxide larger than a second selectivity to the semiconductor material, an etching residue being left on the first layer, (c) etching the etch residue and a surface portion of the second layer by using a second etchant having a third selectivity to the etching residue and the semiconductor material larger than a fourth selectivity to the predetermined material and (d) etching the remaining portion of the second layer by using a third etchant having a fifth selectively to the semiconductor larger than a sixth selectivity to the predetermined material, the ratio of the fifth selectivity to the sixth selectivity being larger than the ratio of the third selectivity to the fourth selectivity.

### BRIEF DESCRIPTION OF THE DRAWINGS

The features and advantages of the process will be more clearly understood from the following description taken in conjunction with the accompanying drawings in which:

FIG. 1A to 1C are cross sectional views showing the prior art process for patterning the silicon oxide layer and the polysilicon layer;

FIG. 2 is a schematic view showing the structure of an etching system used for a process according to the present invention;

FIGS. 3A to 3D are cross sectional views showing a process according to the present invention;

FIGS. 4A and 4B are cross sectional views showing another process according to the present invention;

FIG. 5 is a schematic view showing another etching system used in yet another process according to the present invention; and

FIGS. 6A to 6C are schematic views showing other kinds of etching system available for the process according to the present invention.

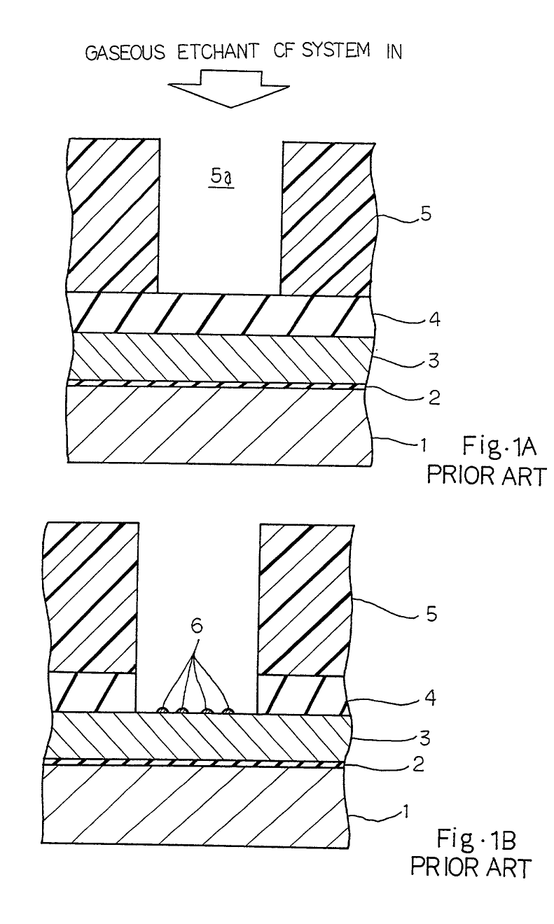

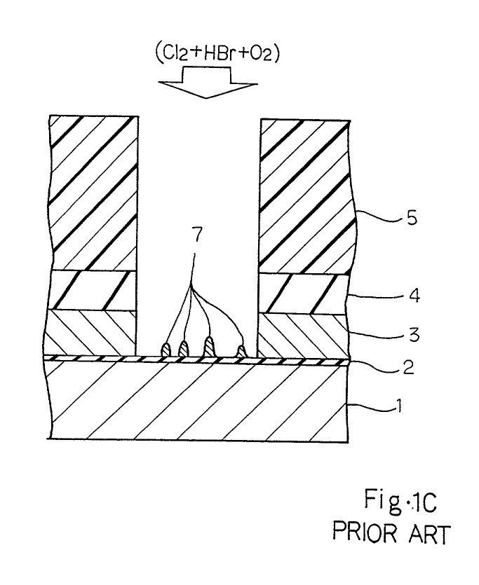

### DESCRIPTION OF THE PREFERRED EMBODIMENTS

First Embodiment

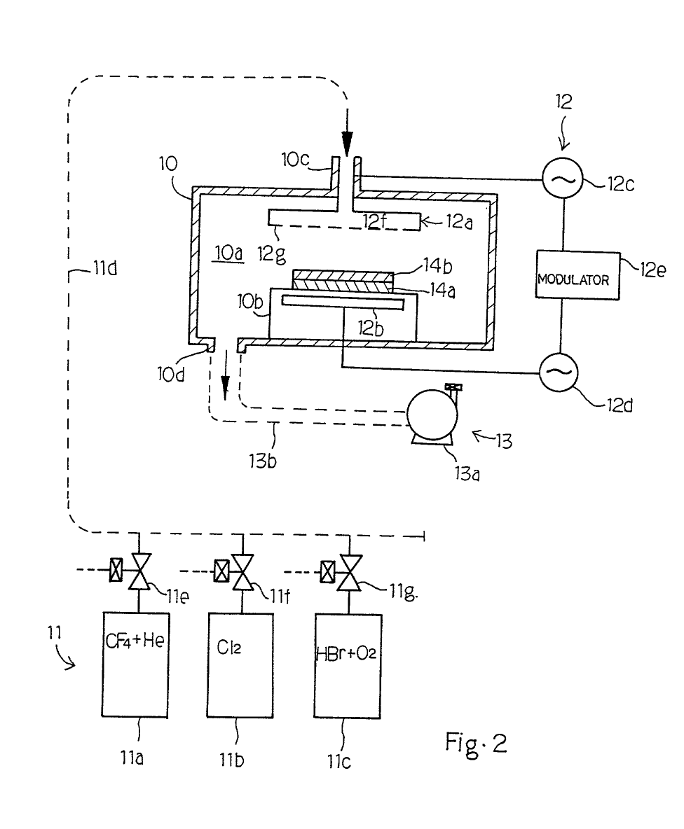

Referring to FIG. 2 of the drawings, a reactive ion etching system largely comprises a reactor 10, a gas supply source 11, a plasma generator 12 and a vacuum source 13. An etching chamber 10a is defined in the reactor, and a wafer stage 10b is placed in the etching chamber 10a. A semiconductor wafer 14a is covered with a multiple-layered structure 14b, and is placed on the wafer stage 10b. A gas inlet 10c and a gas outlet 10d are formed in the reactor 10, and are connected to the gas supply source 13 and the vacuum source 13, respectively.

The gas supply source 11 includes three etching gas sources 11a/11b/11c, a gas pipe 11d and valves 11e/11f/11g connected between the etching gas sources 11a/11b/11c and the gas pipe 11d, respectively. The valves 11e/11f/11g are selectively opened and closed, and three kinds of etching gas is selectively supplied from the etching gas sources 11a/11b/11c through the gas pipe 11d to the etching chamber 10a.

The vacuum source 13 includes a vacuum pump 13a and a gas pipe 13b connected between the gas outlet 10d and the vacuum pump 13a. The vacuum pump 13a evacuates the air and gas from the etching chamber 10a.

The plasma generator 12 includes an upper electrode 12a, a lower electrode 12b, an upper high-frequency power source 12c, a lower high-frequency power source 12d and a modulator 12e. The upper electrode 12a is located over the wafer stage 10b, and is connected to the gas inlet 10c. The etching gas is guided from the gas inlet 10c to an inner space 12f formed in the upper electrode 12a, and blows out from a shower head 12g into the etching chamber 10a. The lower electrode 12b is incorporated in the wafer stage 10b, and is located under the semiconductor wafer 14a.

The upper electrode 12a is connected to the upper high-frequency power source 12c, and the lower electrode 12b is connected to the lower high-frequency power source 12d. The modulator 12e is connected to the upper/lower high-frequency power sources 12c/12d so as to regulate the phase of the upper high-frequency power and the phase of the lower high-frequency power to a predetermined relation. The upper/ lower electrodes 12a/12b are appropriately energized with the high-frequency power, plasma is generated from the etching gas, and the plasma density is of the order of 1×10¹⁰ to 1×10¹¹ cm⁻².

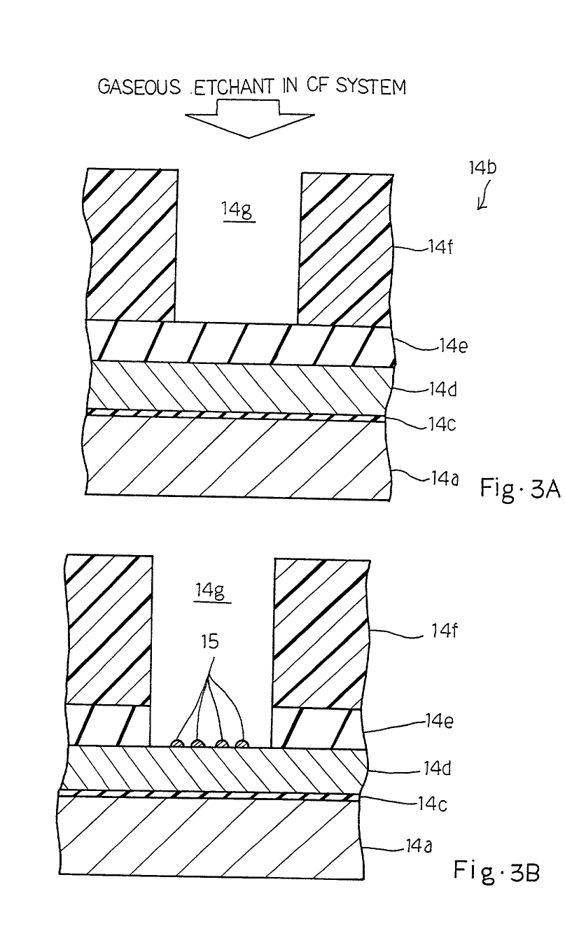

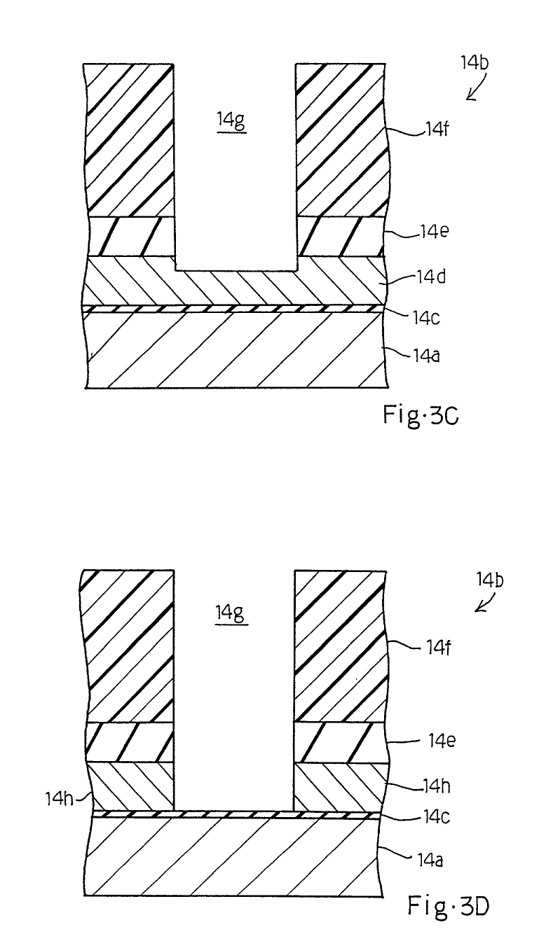

Using the reactive ion etching system, a silicon oxide layer and a polysilicon layer are successively patterned as follows. FIGS. 3A to 3D illustrate a process sequence according to the present invention.

Firstly, the multiple-layered structure 14b is formed on the semiconductor wafer 14a of single crystalline silicon. Silicon oxide is thermally grown to 6-10 nanometers thick on active areas of the semiconductor wafer 14a, and forms silicon oxide layers 14c. The silicon oxide layers 14c serve as gate insulating layers of field effect transistors to be fabricated on the semiconductor wafer 14a. Although plural field effect transistors are to be fabricated on the semiconductor wafer 14a, description is hereinbelow focused on the gate insulating layer and a gate electrode both incorporated in only one of the field effect transistors.

Polysilicon is deposited to 100-150 nanometers thick over the entire surface, and forms a polysilicon layer 14d. The silicon oxide layer 14c is overlain by the polysilicon layer 14d. Subsequently, silicon oxide is deposited to 50-100 nanometers thick over the polysilicon layer 14d, and forms a silicon oxide layer 14e. Photo-resist solution is spread over the entire surface of the silicon oxide layer 14e, and is baked so that a photo-resist layer is formed form the photo-resist layer A pattern image for gate electrodes is transferred from a photo mask (not shown) to the photo-resist layer, and a latent image is formed in the photo-resist layer. The latent image is developed so that a photo-resist etching mask 14f is provided on the silicon oxide layer 14e. The photo-resist etching mask 14f has slits 14g, and the silicon oxide layer 14e is exposed to the slits at intervals as shown in FIG. 3A. The silicon oxide layer 14c, the polysilicon layer 14d, the silicon oxide layer 14e and the photo-resist etching mask 14f form in combination the multiple-layered structure 14b.

The semiconductor wafer 14a laminated with the multiple-layered structure 14b is placed on the wafer stage 10b. The vacuum source 13a starts to evacuate the air from the etching chamber 10a, and the valve 11e is opened. The first etchant is supplied from the etching gas source 11a through the gas pipe 11d to the inner space 12f, and blows out into the etching chamber 10a. The first etching gas contains CHF₄ and He, and the gas flow rate of CF₄ and the gas flow rate of He are regulated to 200 sccm and 50 sccm, respectively. The first etchant may contain CHF₃ or C₄F₈ instead of CF₄. The vacuum source 13 maintains the etching chamber 10a at 20 milli-torr.

The upper high-frequency power source 12c and the lower high-frequency power source 12d respectively supply the upper electrode 12a and the lower electrode 12b the electric power at zero watt and 600 watts, and plasma is generated from the first etching gas. Active species are produced in the plasma, and react with the silicon oxide exposed to the slits 14g. The silicon oxide is removed, and the polysilicon layer 14d is exposed to the slits 14g. Then, the valve lie is closed. Pieces 15 of etching residue are left on the polysilicon layer 14e as shown in FIG. 3B. The pieces 15 of etching residue are fluorocarbon and photo-resist.

Subsequently, the valve 11f is opened, and Cl₂ is supplied from the etching gas source 11b through the gas pipe 11d to the inner space 12f. The gas flow rate of Cl₂ is regulated to 100-200 sccm. The vacuum source 13 maintains the etching chamber 10a at 5-20 milli-torr. The upper high-frequency power source 12c and the lower high-frequency power source 12d supply the upper electrode 12a and the lower electrode 12b 200-600 watts and 50-200 watts, and the modulator 12e regulates the phase difference between the upper high-frequency power and the lower high-frequency power to 180 degrees. Plasma is generated from the second gaseous etchant, and the active species react with the etching residue 15 and the polysilicon. The etching rate for the polysilicon ranges between 100 nanometers per minute and 200 nanometers per minute. However, the silicon oxide is etched at 15-30 nanometers per minute. Thus, the selectivity is not large. For this reason, when the etching residue 15 are removed, the second reactive ion etching is stopped, and the silicon oxide layer 14c is still covered with the polysilicon layer 14d as shown in FIG. 3C.

Subsequently, the valve 11g is opened, and the third gaseous etchant is supplied from the etching gas source 11c through the gas pipe 11d to the inner space 12f. The third etching gas blows out from the shower head 12g to the etching chamber 10a. The gas flow rate of HBr is regulated to 100-200 sccm, and the gas flow rate of O₂ is regulated to 2-10 sccm. The vacuum source 13 regulates the etching chamber 10a to 50-150 milli-torr. The upper high-frequency power source 12c and the lower high-frequency power source 12d supply the upper electrode 12a and the lower electrode 12b the high-frequency power at 200-600 watts and 50-200 watts, respectively. The modulator 12e regulates the phase difference between the upper high-frequency electric power and the lower high-frequency electric power to 135 degrees.

Active species selectively removes the polysilicon until the silicon oxide layer 14c is exposed, and the polysilicon layer 14d is formed into the gate electrodes 14h as shown in FIG. 3D. The third etching gas has a selectivity of the polysilicon to the silicon oxide larger than the selectivity of the second etching gas. For this reason, the silicon oxide layer 14c is never damaged, and the polysilicon layer 14d is patterned into the gate electrodes. As described hereinbefore, the pieces of etching residue 15 have been etched away during the second etching, and the third etching is carried out without any unintentional etching mask. For this reason, any piece of residual polysilicon is left on the silicon oxide layer 14c.

As will be understood from the foregoing description, the pieces of etching residue are etched away together with a part of the polysilicon layer 14d, and, thereafter, the polysilicon layer 14d is patterned into the gate electrodes 14h without any residual polysilicon. While the second etching is carried out with the second etching gas, the polysilicon layer 14d is partially patterned, and the third etching is completed earlier than the second etching of the prior art process.

Second Embodiment

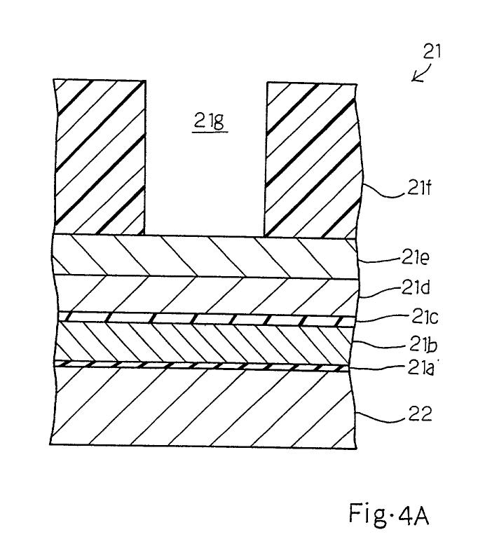

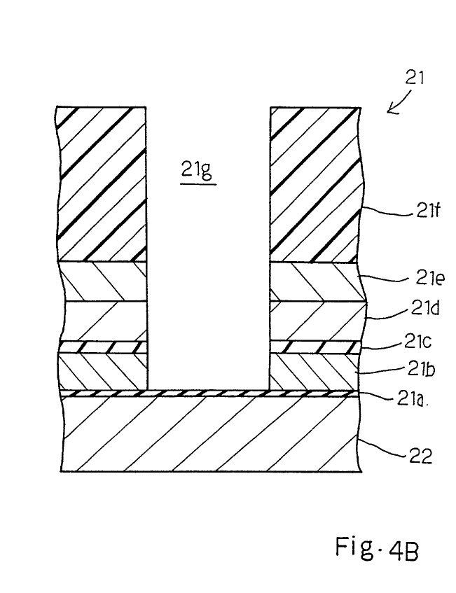

FIGS. 4A and 4B illustrate another process embodying the present invention. The process starts with preparation of a laminated structure 21 formed on a silicon wafer 22. A gate structure of a floating gate type field effect transistor is patterned from the laminated structure 21. The laminated structure 21 includes a silicon oxide layer 21a for a gate insulating layer, a polysilicon layer 21b for a floating gate electrode deposited on the silicon layer 21a, a composite insulating layer 21c for an inter-gate insulating layer formed on the polysilicon layer 21b, a polysilicon layer 21d and a tungsten silicide layer 21e for a control gate electrode successively deposited on the composite insulating layer 21c. In this instance, the composite insulating layer 21c consists of a silicon nitride layer sandwiched between two silicon oxide layers.

The laminated structure 21f further includes a photo-resist etching mask 21f, and the photo-resist etching mask 21f is patterned through the lithographic techniques as similar to the photo-resist etching mask 14f. Slits 21g are formed in the photo-resist etching mask 14f at intervals, and only one slit 21g is shown in FIGS. 4A and 4B. The tungsten silicide layer 21e is exposed to the slits 21g as shown in FIG. 4A.

The resultant structure, i.e., the semiconductor wafer 22 and the laminated structure 21 are placed on the wafer table of a reactive ion etching system. The reactive ion etching system is similar to that shown in FIG. 2 except etching gas sources as described hereinbelow.

First, gaseous etchant containing Cl₂ and O₂ is introduced into the etching chamber, and the gaseous etchant selectively removes the tungsten silicide layer 21e, and the polysilicon layer 21d is exposed to the slit 21g. The gaseous etchant is changed to another gaseous etchant containing Cl₂ and HBr, and the second gaseous etchant selectively removes the polysilicon layer 21d. The composite insulating layer 21c is exposed to the slit 21g.

Subsequently, the composite insulating layer 21c and the polysilicon layer 21b are successively etched under the same conditions for the silicon oxide layer 14e and the polysilicon layer 14d. Upon completion of the etching for patterning the composite insulating layer 21c, etching residue is left on the polysilicon layer 21b, and the etching residue is removed together with a surface portion of the polysilicon layer 21b as similar to the first embodiment. For this reason, any piece of polysilicon is never left on the silicon oxide layer 21a as shown in FIG. 4B.

Third Embodiment

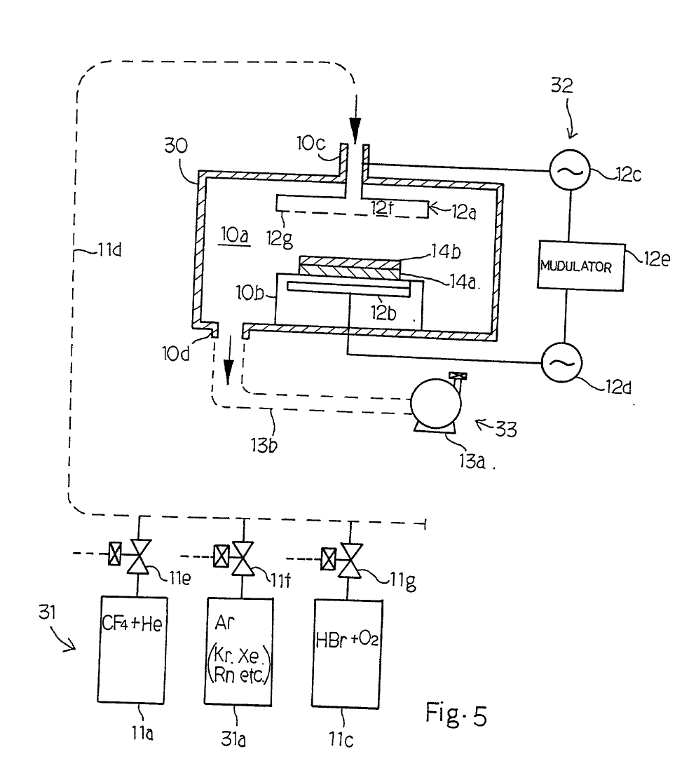

Turning to FIG. 5 of the drawings, a reactive ion etching system largely comprises a reactor 30, a gas supply source 31, a plasma generator 32 and a vacuum source 33. The reactor 30, the gas supply source 31, the plasma generator 32 and the vacuum source 33 are similar to the reactor 10, the gas supply source 11, the plasma generator 12 and the vacuum source 13 except the etching gas source 31a. For this reason, the components are labeled with the same references designating corresponding components of the reactive ion etching system shown in FIG. 2 without detailed description.

The etching gas source 31a supplies a kind of noble gas such as Ar, Kr, Xe, Rn etc. to the etching chamber 10a. While the etching gas source 31a is supplying the noble gas to the etching chamber 10a, the upper high-frequency power source 12c and the lower high-frequency power source 12d apply bias voltage between 400-600 watts between the upper electrode 12a and the lower electrode 12b. For this reason, the sputter etching is carried out, and pieces of etching residue and a surface portion of a semiconductor layer are subjected to the ion bombardment. As a result, the pieces of etching residue and the surface portion of the semiconductor layer are removed.

The reactive ion etching system shown in FIG. 5 is available for the processes implementing the first and second embodiments. The etching using Cl₂ gas is replaced with the sputter etching, and the other steps are identical with those of the first embodiment or the second embodiment. The sputter etching is less selective between the polysilicon and the silicon oxide. For this reason, the polysilicon layer 21b is finally patterned by using the etching gas containing the HBr and O₂. The etching gas has a large selectivity between the polysilicon and the silicon oxide.

As will be appreciated from the foregoing description, the pieces of etching residue are removed before the patterning for the polysilicon layer, and any piece of polysilicon is never left on the lower silicon oxide layer.

Although particular embodiments of the present invention have been shown and described, it will be apparent to those skilled in the art that various changes and modifications may be made without departing from the spirit and scope of the present invention.

For example, the polysilicon layer to be etched after the silicon oxide layer may be replaced with an amorphous silicon layer, a single crystalline silicon layer or another semiconductor layer.

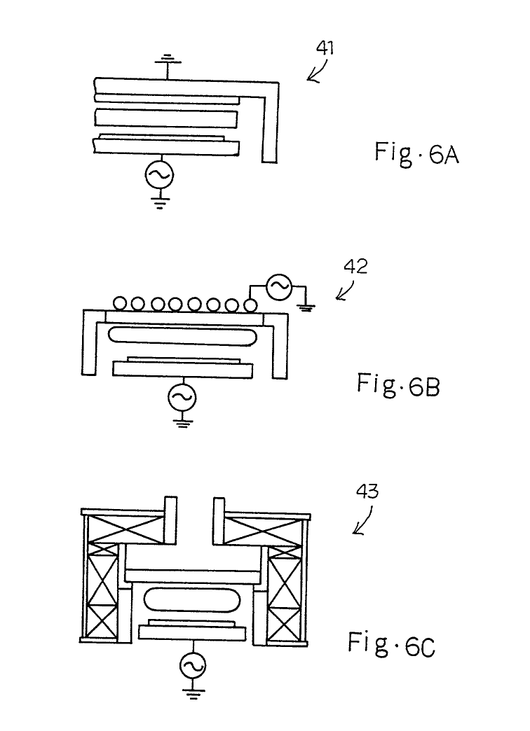

Various etching systems are available for the process according to the present invention. Another kind of RIE (Reactive Ion Etching) system 41, an ICP etching system 42 and an ECR (Electron Cyclotron Resonance) reactive ion stream etching system 43 available for the process are shown in FIGS. 6A, 6B and 6C, respectively.

What is claimed is:

1. A process for fabricating a semiconductor device, comprising the steps of:
(a) preparing a semiconductor structure having a first layer formed of a predetermined material, a second layer formed of a semiconductor material and laminated on said first layer and a third layer formed of an oxide and laminated on said second layer;
(b) etching said third layer by using a first etchant having a first selectivity to said oxide than a second selectivity to said semiconductor material, an etching residue being left on said first layer;
(c) etching said etch residue and a surface portion of said second layer by using a second etchant having a third selectivity to said etching residue and said semiconductor material larger than a fourth selectivity to said predetermined material; and
(d) etching the remaining portion of said second layer by using a third etchant having a fifth selectively to said semiconductor material larger than a sixth selectivity to said predetermined material, the ratio of said fifth selectivity to said sixth selectivity being larger than the ratio of said third selectivity to said fourth selectivity.

2. The process as set forth in claim 1, in which said first etchant contains a gaseous component in the CF system, and said second etchant is Cl₂ gas.

3. The process as set forth in claim 2, in which said gaseous component is selected from the group consisting of CF₄, CHF₃ and C₄F₈.

4. The process as set forth in claim 2, in which said oxide is silicon oxide, and said etching residue contains fluorocarbon produced during the etching using said first etchant containing said gaseous component in the CF system.

5. The process as set forth in claim 2, in which said oxide, said semiconductor material and said predetermined material are silicon oxide, silicon and silicon oxide, respectively, and said etching residue contains fluorocarbon produced during the etching using said first etchant containing said gaseous component in the CF system.

6. The process as set forth in claim 5, in which said third etchant contains HBr and O₂ so as to achieve said ratio of said fifth selectivity to said sixth selectivity larger than said ratio of said third selectivity to said fourth selectivity.

7. The process as set forth in claim 5, in which said silicon has one of the single crystal structure, the polycrystal structure and the amorphous structure.

8. The process as set forth in claim 5, in which a dry etching system is used for said steps (b), (c) and (d) without taking out said semiconductor structure from an etching chamber of said dry etching system.

9. The process as set forth in claim 8, in which said dry etching system includes a plasma generator having a first electrode and a second electrode provided on both sides of said semiconductor structure, and said etching in said step (c) is carried out under the conditions where
a flow rate of said Cl₂ gas ranging 100 sccm to 200 sccm,
a pressure in said etching chamber ranging from 5 milli-torr to 20 milli-torr,
a first high-frequency electric power at said first electrode ranging from 200 watts to 600 watts,
a second high-frequency electric power at said second electrode ranging from 50 watts to 200 watts, and
a phase difference between said first high-frequency electric power and said second high-frequency electric power being regulated to 180 degrees.

10. The process as set forth in claim 2, in which said oxide, said semiconductor material and said predetermined material are silicon oxide wrapping silicon nitride, silicon and silicon oxide, respectively, and said etching residue contains fluorocarbon produced during the etching using said first etchant containing said gaseous component in the CF system.

11. The process as set forth in claim 10, in which said third etchant contains HBr and O₂ so as to achieve said ratio of said fifth selectivity to said sixth selectivity larger than said ratio of said third selectivity to said fourth selectivity.

12. The process as set forth in claim 10, in which said silicon has one of the single crystal structure, the polycrystal structure and the amorphous structure.

13. The process as set forth in claim 10, in which a dry etching system is used for said steps (b), (c) and (d) without taking out said semiconductor structure from an etching chamber of said dry etching system.

14. The process as set forth in claim 13, in which said dry etching system includes a plasma generator having a first electrode and a second electrode provided on both sides of said semiconductor structure, and said etching in said step (c) is carried out under the conditions where
a flow rate of said Cl₂ gas ranging 100 sccm to 200 sccm,
a pressure in said etching chamber ranging from 5 milli-torr to 20 milli-torr,
a first high-frequency electric power at said first electrode ranging from 200 watts to 600 watts,
a second high-frequency electric power at said second electrode ranging from 50 watts to 200 watts, and
a phase difference between said first high-frequency electric power and said second high-frequency electric power being regulated to 180 degrees.

15. The process as set forth in claim 1, in which said second etchant is a kind of noble gas, and ions are attracted from a plasma created from said noble gas under a large bias voltage ranging from 400 volts to 600 volts toward said semiconductor structure.

16. The process as set forth in claim 15, in which said first etchant contains a gaseous component selected from the group consisting of CF₄, CHF₃ and C₄F₈.

17. The process as set forth in claim 16, in which said oxide is silicon oxide, and said etching residue contains fluorocarbon produced during the etching using said first etchant.

18. The process as set forth in claim 16, in which said oxide, said semiconductor material and said predetermined material are silicon oxide, silicon and silicon oxide, respectively, and said etching residue contains fluorocarbon produced during the etching using said first etchant.

19. The process as set forth in claim 18, in which said third etchant contains HBr and O₂ so as to achieve said ratio of said fifth selectivity to said sixth selectivity larger than said ratio of said third selectivity to said fourth selectivity.

20. The process as set forth in claim 18, in which said silicon has one of the single crystal structure, the polycrystal structure and the amorphous structure.

21. The process as set forth in claim 18, in which a dry etching system is used for said steps (b), (c) and (d) without taking out said semiconductor structure from an etching chamber of said dry etching system.

22. The process as set forth in claim 15, in which said oxide, said semiconductor material and said predetermined material are silicon oxide wrapping silicon nitride, silicon and silicon oxide, respectively, and said etching residue contains fluorocarbon produced during the etching using said first etchant containing said gaseous component.

23. The process as set forth in claim 22, in which said third etchant contains HBr and O₂ so as to achieve said ratio of said fifth selectivity to said sixth selectivity larger than said ratio of said third selectivity to said fourth selectivity.

24. The process as set forth in claim 22, in which said silicon has one of the single crystal structure, the polycrystal structure and the amorphous structure.

25. The process as set forth in claim 15, in which a dry etching system is used for said steps (b), (c) and (d) without taking out said semiconductor structure from an etching chamber of said dry etching system.

26. The process as set forth in claim 1, in which said step (b) includes the substeps of
(b-1) providing a photo-resist etching mask on said third layer, and
(b-2) selectively etching said third layer by using said first etchant, said etching residue being left on a surface of said first layer exposed to an opening formed in said photo-resist etching mask, and
said step (c) and said step (d) are carried out without removing said photoresist etching mask.

27. The process as set forth in claim 26, in which said oxide, said semiconductor material and said predetermined material are silicon oxide, silicon and silicon oxide, respectively.

28. The process as set forth in claim 27, in which said first etchant, said second etchant and said third etchant are a gaseous etchant containing etching component in the CF system, Cl₂ and another etchant containing HBr and O₂, respectively.

29. The process as set forth in claim 28, in which said Cl₂ is replaced with a noble producing a plasma under a bias condition ranging from 400 watts to 600 watts for an ion bombardment to said etching residue and said surface portion of said second layer.

30. The process as set forth in claim 26, in which said oxide, said semiconductor material and said predetermined material are silicon oxide wrapping silicon nitride, silicon and silicon oxide, respectively.

31. The process as set forth in claim 30, in which said first etchant, said second etchant and said third etchant are a gaseous etchant containing etching component in the CF system, Cl₂ and another etchant containing HBr and O₂, respectively.

32. The process as set forth in claim 30, in which said Cl₂ is replaced with a noble producing a plasma under a bias condition ranging from 400 watts to 600 watts for an ion bombardment to said etching residue and said surface portion of said second layer.
